(19) United States
(12) Patent Application Publication
(10) Pub. No.: US 2026/0141139 A1
(43) Pub. Date: May 21, 2026

(54) Machine Learning Systems and Methods for Improved Statistical Downscaling for Extreme Weather Event Modeling Using Generative Diffusion Models

(71) Applicant: Insurance Services Office, Inc., Jersey City, NJ (US)

(72) Inventors: Rahul Sundar, Hyderabad (IN); Yucong Hu, Toronto (CA); Nishant Parashar, Saharanpur (IN); Antoine Blanchard, Boston, MA (US); Boyko Dodov, Mansfield, MA (US)

(73) Assignee: Insurance Services Office, Inc., Jersey City, NJ (US)

(21) Appl. No.: 19/394,558

(22) Filed: Nov. 19, 2025

Related U.S. Application Data
(60) Provisional application No. 63/722,404, filed on Nov. 19, 2024.

(51) Int. Cl. G06F 30/27; G06N 3/0455

(52) U.S. Cl. CPC G06F 30/27; G06N 3/0455

(57) ABSTRACT

Machine learning systems and methods for extreme weather event modeling using generative diffusion models are provided. The system includes a weather modeling processor and a weather modeling engine executed by the processor. The weather modeling engine causes the processor to: receive a dataset including a plurality of vorticity samples; process the dataset using a deterministic mean model having a temporal attention unit to model spatial, cross-channel, and temporal dependencies using dynamical attention units; and process output of the deterministic mean model using a reverse diffusion model to capture stochastic fine scale features and to generate a denoised output. A downscaling pipeline can also be executed by the weather modeling engine to downscale outputs of the system.

### RELATED APPLICATIONS

The present application claims the benefit of U.S. Provisional Application Ser. No. 63/722,404 filed on Nov. 19, 2024, the entire disclosure of which is expressly incorporated herein by reference.

### BACKGROUND

### Technical Field

The present disclosure relates generally to the field of computerized weather modeling. More specifically, the present disclosure relates to machine learning systems and methods for extreme weather event modeling using generative diffusion models.

### Related Art

Weather extremes are on the rise due to accelerated climate change. Given their potential to severely damage life and property, it is becoming increasingly important to estimate their frequency, associated risks and economic losses beforehand, using accurate and reliable computer modeling techniques. By insuring for such losses, it is possible to become more resilient towards extreme events. Computerized climate risk modeling often relies on historical Earth system observations or physics-based general circulation models (GCMs) to generate climate projections. Typically, GCMs operate at a coarse resolution (O(10)-O(10²)km) due to computational limitations of existing computerized modeling systems. This leads to incorrect characterization of weather extremes. In recent years, machine-learning-based statistical downscaling approaches have been explored to obtain realistic well-resolved climate data over specific regions. These methods leverage historical Earth system observation data to create a non-linear mapping from bias-corrected coarse GCM simulations to the desired higher-resolution outputs.

While deterministic regression models effectively capture large-scale features, they struggle with fine-scale stochastic atmospheric processes due to low-frequency spectral bias. This limitation has recently led to the adoption of generative models like generative adversarial networks (GANs), and denoising diffusion models for downscaling tasks. Denoising diffusion models are particularly promising due to their stability in training, reliable convergence, and high output quality. However, sampling is often time consuming. Addressing this, one approach explored the design space of such diffusion models and proposed the elucidated diffusion model (EDM) which successfully reduced the number of model evaluations (from O(10³) to O(10)) required to generate a single sample. Motivated by this, a correction diffusion model (CorrDiff) was proposed for kilometer-scale downscaling. CorrDiff combined a UNet-based deterministic model to map the mean field and an EDM correction to capture fine-scale stochastic content.

In the context of computerized extreme-event simulation, it is vital that both short- and long-term event statistics of downscaled data be consistent with historical observations. As a result, the lack of temporal modeling in downscaling models may affect dynamical consistency of downscaled data (e.g. distorted propagation of storm fronts). One could address this issue by borrowing techniques from video generation/prediction for regional weather forecasting. However, such techniques have not yet been explored for downscaling. Moreover, large models are computationally intensive to train and infer. This prohibits the generation of even relatively small (O(10³)) extreme-event datasets, which are crucial for accurately quantifying climate tail risk. Given a good mean-field model, it is possible that a smaller and computationally efficient diffusion model would suffice. This would reduce overall computational demands, inference times, and improve efficiency for real-time use.

Accordingly, what would be desirable, but have not yet been provided, are machine learning systems and methods for extreme weather event modeling using generative diffusion models which address the foregoing and other needs.

### SUMMARY

The present disclosure relates to machine learning systems and methods for extreme weather event modeling using generative diffusion models. The system includes a weather modeling processor and a weather modeling engine executed by the processor. The weather modeling engine causes the processor to: receive a dataset including a plurality of vorticity samples; process the dataset using a deterministic mean model having a temporal attention unit to model spatial, cross-channel, and temporal dependencies using dynamical attention units; and process output of the deterministic mean model using a reverse diffusion model to capture stochastic fine scale features and to generate a denoised output. A downscaling pipeline can also be executed by the weather modeling engine to downscale outputs of the system.

### BRIEF DESCRIPTION OF THE DRAWINGS

The foregoing features of the invention will be apparent from the following Detailed Description of the Invention, taken in connection with the accompanying drawings, in which:

FIG. 1 is a diagram illustrating the machine learning systems and methods of the present disclosure;

FIG. 2 is a diagram illustrating implementation of the system of FIG. 1 in connection with quantile mapping and reanalysis systems;

FIGS. 3-6 illustrate testing and performance of the systems and methods of the present disclosure;

FIG. 7 is a schematic diagram illustrating a downscaling pipeline capable of being implemented by the systems and methods of the present disclosure; and

FIG. 8 illustrate testing and performance of the downscaling pipeline of FIG. 7.

### DETAILED DESCRIPTION

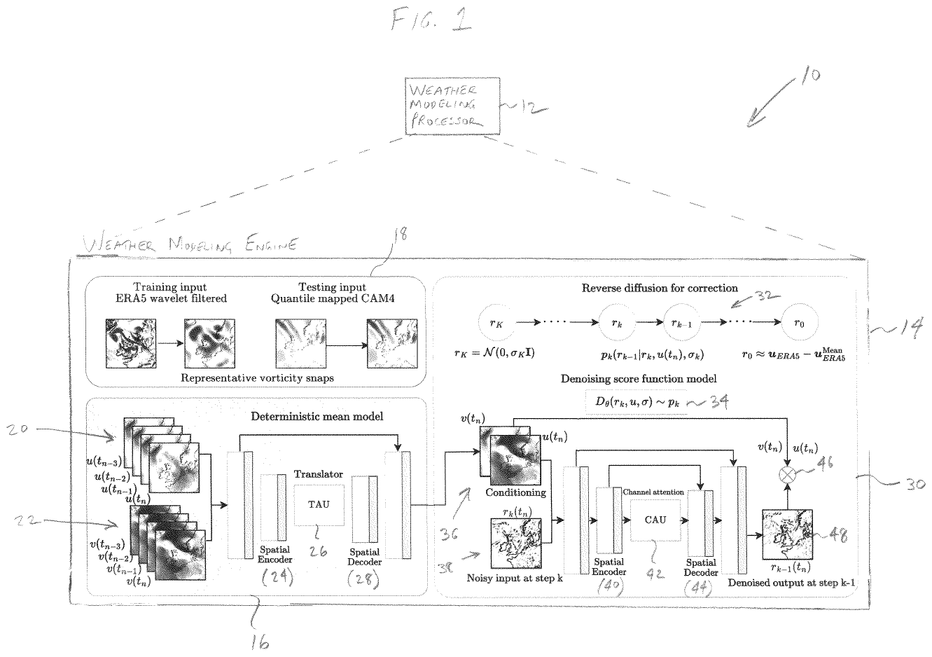

The present disclosure relates to machine learning systems and methods for extreme weather event modeling using generative diffusion models, as discussed in greater detail below in connection with FIGS. 1-8.

As will be discussed in greater detail below, the systems and methods of the present disclosure provide a computationally efficient “Temporal Attention Unit enhanced Diffusion” (TAUDiff) model that integrates (a) a video prediction model for dynamically consistent mean-field downscaling, and (b) a smaller guided denoising diffusion model for stochastically generating the fine-scale features. The models can be trained on atmospheric wind fields obtained from a reanalysis dataset. The system produces accurate and computationally efficient extreme-event datasets, and with reduced model inference times and carbon footprint offsetting.

FIG. 1 is a diagram illustrating the machine learning systems and methods of the present disclosure, indicated generally at 10. The system includes a weather modeling processor 12 and a weather modeling engine 14 executed by the processor 12. The engine 14 includes training and testing inputs 18, a deterministic mean model 16 which functions as a video prediction model for dynamically consistent mean-field downscaling, and a reverse diffusion model 30 which functions as a denoising diffusion model for stochastically generating the fine-scale features. The training and testing inputs 18 include, but are not limited to, vorticity datasets (snaps) including wavelet-filtered ERA5 training input datasets and quantile-mapped CAM4 testing input datasets. Once trained, the model 16 processes a dataset including a plurality of vorticity samples 20, 22. The model 16 includes a spatial encoder 24, a translator model 26, and a spatial decoder 28. Output of the model 16 is then processed by the reverse diffusion model 30, which includes reverse diffusion processes 32, a denoising score function model 34, model conditioning module 36, and one or more noisy inputs 38. Additionally, the model 30 includes a spatial encoder 40, a channel attention unit 42, and a spatial encoder 44, and produces a denoised output 48. The denoised output 48 can be mixed by module 46 with outputs of the conditioning module 36 to fine-tune the model 30.

The engine 14 adopts an architecture including a spatial backbone, and a translator for temporal modelling, ensuring temporal coherence and simplicity as compared to the more complex transformer-based architectures. A UNet can be utilized for the spatial backbone, and the temporal attention unit (TAU) 26 for the translator. The TAU 26 first independently models spatial dependency via static, and both cross-channel and temporal dependencies using dynamical attention units, respectively, and then combines them. The mean model 16 is trained using a weighted combination of mean absolute error (MAE), mean squared error (MSE), and to additionally maintain dynamical consistency, physics-based losses on advection (u·∇u), vorticity (∇×u) and divergence (∇·u) of wind fields (u) are also considered. Although dynamically consistent predictions are possible with the mean model 16, the downscaled fields still lack the stochastic fine scale features. These are addressed by the model 30.

To capture the residual stochastic fine scale features (which cannot be captured by the mean model), the diffusion model 30 (which has ˜O(1) million (M) parameters) was trained using a score-matching loss. To maintain consistency, the model 30 implements a SimVP architecture as in the mean model 16 but with a residual dense UNet as the spatial backbone. Once the model is trained, a data sample can be generated by solving a stochastic differential equation modelling a reverse diffusion process. Since the conditional input to the diffusion model 30 is the mean model 16 output (for a single time instance), the TAU 26 is changed into the Channel Attention Unit (CAU) 42 where the dynamical attention unit now models cross-channel dependencies and their relative importance.

As will be discussed below, the efficacy of engine 14 in downscaling atmospheric wind fields over the European region was tested. For training, the system utilized the atmospheric reanalysis dataset (ERA5) at 0.25° lat-lon resolution produced by the European Center for Medium-range Weather Forecasts (ECMWF). Instead of a single time instance input, the system uses a deterministic regression component that takes a temporal sequence of coarsened ERA5 wind velocity snapshots with orography data as input. Here, the high-resolution ERA5 wind fields from the final time step of the sequence serves as the target. Instead of using coarse interpolation, the system uses lowpass spherical wavelet filtering to create band-limited low-resolution ERA5 fields to ensure proper scale separation. This approach closely mirrors real-world scenarios where bias-corrected GCM data lacks fine-scale spatio-temporal features. The system uses the Community Atmosphere Model 4.0 (CAM4) (at 1° lat-lon resolution) as the coarse GCM.

It is noted that the weather modeling processor 12 could be any suitable computing system capable of executing the weather modeling engine 14, including a standalone computer system (e.g., personal computer, laptop computer, desktop computer, tablet computer, smart phone, etc.), a server, or a cloud-based computing platform. The engine 14 could be embodied as non-transitory, computer-readable instructions stored on a computer-readable storage medium (memory) and coded in any suitable high- or low-level computer programming language, including, but not limited to, C, C++, C#, Java, Python, or any other suitable language.

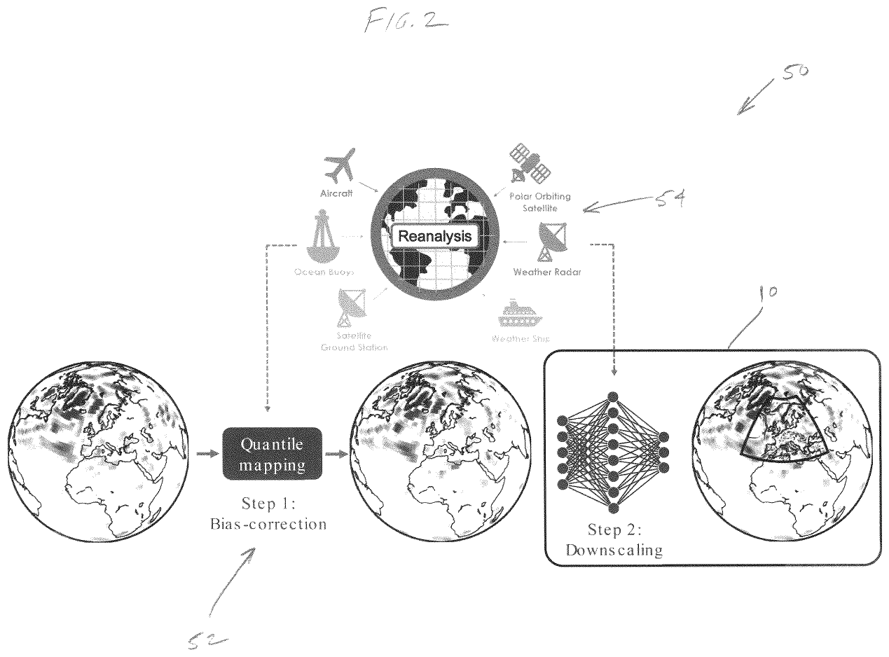

FIG. 2 is a diagram illustrating implementation of the system of FIG. 1 in connection with quantile mapping and reanalysis systems. More specifically, the system 10 processes weather data after bias correction processes 52 (involving quantile mapping) have been performed on the weather data, as well as reanalysis data 54 generated by one or more systems including, but not limited to, aircraft, ocean buoys, satellite ground stations, polar orbiting satellites, weather radar, and weather ships. Advantageously, the system 10 provides a machine learning (ML) pipeline for downscaling physics-based GCM simulations.

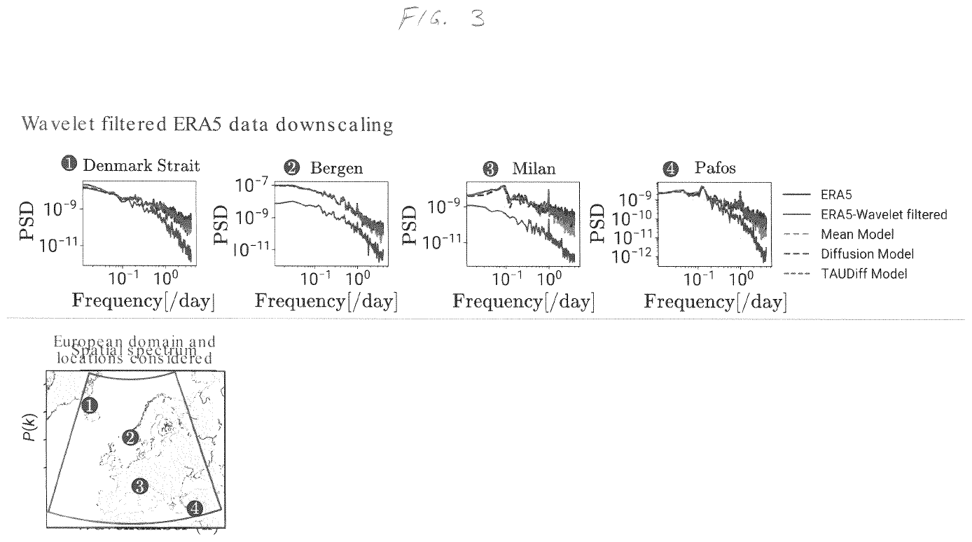

FIGS. 3-6 illustrate testing and performance of the systems and methods of the present disclosure.

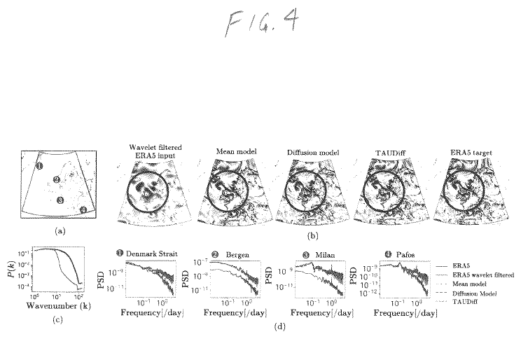

As shown in FIGS. 3-4, the system performance (“TAUDiff”) is compared against a deterministic mean-field regression and an end-to-end diffusion, each with O(10)M trainable parameters overall. These models were trained over 40 years of ERA5 atmospheric wind data over Europe (1980-2020) (graph (a) shown in FIG. 4) and validated over 2021-23. All the models were trained on a single T4 graphics processing unit (GPU) over 50 epochs, with training times of 24, 48, and 60 hours for the mean, end-to-end diffusion, and the TAUDiff models, respectively. Graph (a) in FIG. 4 depicts the European region used for training the downscaling models, with select locations used for evaluating performance. Comparison of model predictions is shown in Graphs (b) of FIG. 4, which show vorticity snapshots at UTC: 2023-12-31 21:00. Graph (c) of FIG. 4 shows the spatial spectrum, and Graph (d) of FIG. 4 shows the temporal spectra at select locations shown in Graph (a) of FIG. 4. Qualitatively, the vorticity contour predictions of mean and TAUDiff models demonstrate dynamical consistency of storm fronts, whereas the end-to-end diffusion model distorts them due to noise injection (see the circled zone in the Graphs (b) of FIG. 4). Quantitatively, pointwise statistics computed over validation years 2021-23 show good recovery of spatial and temporal spectrum for the systems and methods of the present disclosure (“TAUDiff”), while mean model underrepresents, and end-to-end diffusion overrepresents higher temporal frequencies, respectively (see Graphs (c) and (d) of FIG. 4).

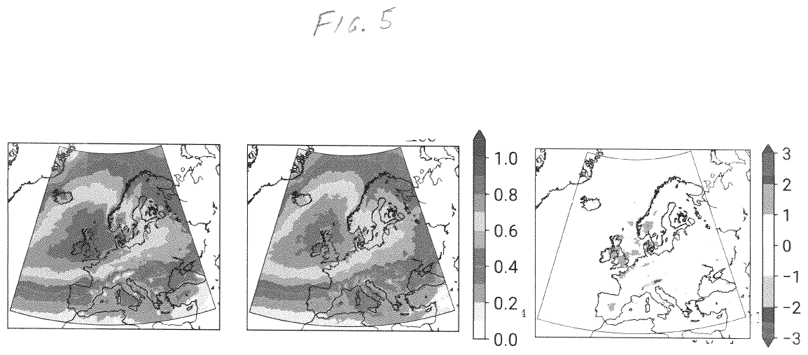

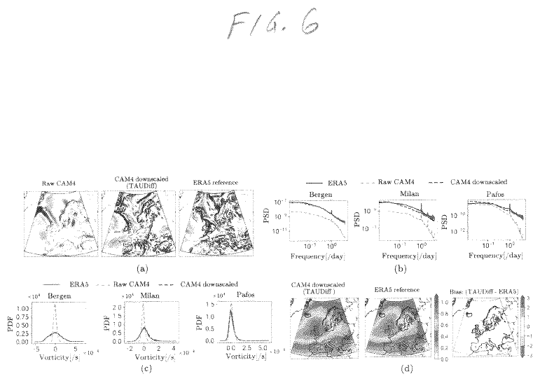

As illustrated in FIGS. 5-6, the performance of the system was then evaluated on downscaling bias corrected CAM4 obtained wind fields over 40 years. Bias correction is done by quantile-mapping the 40-year distribution of each grid cell to that of ERA5, wavelet-filtered to GCM resolution. As shown in Graphs (a-c) of FIG. 6, physically consistent output, and remarkable spectral recovery were produced. Although only a simple quantile mapping is adopted for bias correction, the system generates good agreement with ERA5 ground truth in the local storm counts (see Graphs (d) of FIG. 6 (also illustrated in FIG. 5)). Graph (a) of FIG. 6 illustrates an assessment of downscaling performance on bias corrected CAM4 data. Graph (b) of FIG. 6 illustrates temporal spectrum. Graph (c) illustrates an assessment of vorticity distributions. Graph (d) of FIG. 6 illustrates local storm counts.

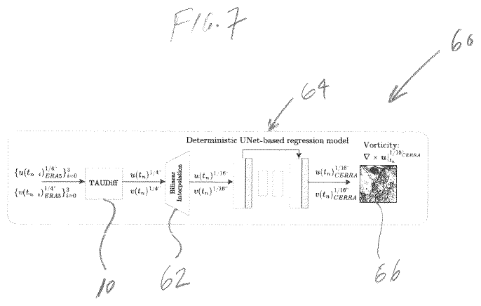

FIG. 7 is a schematic diagram illustrating a downscaling pipeline, indicated generally at 60, capable of being implemented by the systems and methods of the present disclosure. The pipeline 60 includes a system 10 (“TAUDiff”), a bilinear interpolation module 62 which processes outputs of the system 10, and a deterministic UNet-based regression model 64 which processes outputs of the bilinear interpolation module 62 to produce a vorticity contour 66. Diffusion models require multiple function evaluations while sampling. As a result, in case of km-scale regional downscaling, ensemble methods, a large model size, and high image resolutions can vastly increase the inference times. Hence, for applications necessitating km-scale downscaling, it would be beneficial to have the system 10 operate at a coarser resolution to reduce computational inference times, and this is achieved by the pipeline 60. Since the models can be trained on reanalysis data, a single ensemble member of the diffusion model should be representative of the field-statistics. The generated samples at coarser resolution can then be downscaled using the deterministic UNet-based regression model 64 to recover the fine-resolution data as depicted in FIG. 7.

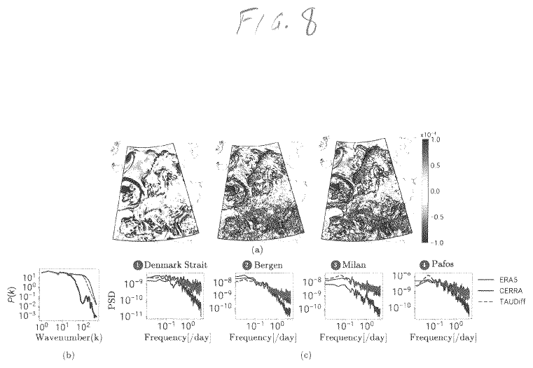

FIG. 8 illustrate testing and performance of the downscaling pipeline of FIG. 7. The system downscaled the ERA5 atmospheric wind velocity fields at 0.25° resolution to the Copernicus European Regional Reanalysis (CERRA) dataset resolution of 0.0625°. The CERRA dataset is natively obtained on a cartesian grid. However, the system projected the CERRA data onto a lat-lon grid of similar resolution. The system considered the entire European region for training as shown in Graph (a) of FIG. 4. FIG. 8 illustrates an assessment of ERA5 to CERRA downscaling performance, such that Graphs (a) of FIG. 8 illustrates vorticity contours at UTC: 2010-11-10 21:00, Graph (b) of FIG. 8 illustrates spatial spectrum, and Graphs (c) illustrate temporal spectra at select locations as shown in Graph (a) of FIG. 4. While the size of the mean model component of the system remains the same as in the earlier experiments, the correction-diffusion, and the deterministic UNet-based regression models were O(10)M, and O(10²) thousand trainable parameters, respectively. This is to ensure that the finer scales are well captured by the models. The system was trained over 10 years (2011-2020) of input-target pairs of ERA5, and 0.25° interpolated CERRA over the European region (see Graph (a) of FIG. 4) and tested over the year 2010. The deterministic UNet-based regression model was independently trained over the same domain using high resolution CERRA wind velocity fields as targets, and interpolated CERRA wind velocity fields as the model inputs. At inference, we chain the system of the present disclosure and the regression model together to generate a sample.

The systems and methods of the present disclosure generated physically consistent fields with good qualitative and quantitative agreement with CERRA data (see FIG. 8). If one were to pass inputs at 0.0625° resolution to the diffusioncorrection model, it can take approximately 76 minutes for downscaling one year on a single NVIDIA H100 GPU. However, since the system operates at 0.25° resolution, it obtains a reasonable inference time of approximately 4 minutes per one year of data. In both cases, 20 reverse diffusion steps were considered. With frameworks like NVIDIA TensorRT, it is also possible to further reduce the inference times by up to three times the original.

Overall, the systems and methods of the present disclosure, as well as the km-scale downscaling extension (pipeline) discussed above generate dynamically consistent downscaling, remarkable reconstruction of spatio-temporal fine scale features, and viable computational inference times with the use of a small correction diffusion model. Since coarse and fine scale content of the atmospheric fields are resolved well, accurate estimation of storm statistics is possible, and excellent performance on spectrum and storm statistics can be obtained. Even when the system is operated on coarser resolutions, the ERA5-to-CERRA downscaling performance is remarkable. Thus, the systems and methods of the present disclosure generate accurate and computationally efficient estimation of extreme weather events, thus significantly improving computational weather modeling from computational efficiency and accuracy perspectives. Further, the systems and methods disclosed herein can be staged to obtain multi-resolution outputs for extreme weather event simulations while maintaining reasonable inference times.

The smaller models of the systems and methods of the present disclosure have low inference times, which also results in a lower carbon footprint. With the size of O(10)M parameters, the diffusion model component is only O(1)M parameters. This allows for efficient inference and enables operationalization at scale. For inference, on just one year's worth of 3-hourly resolved wind fields over Europe, it takes approximately 30 minutes of computer execution time on a single T4 GPU, and about 4 minutes of computer execution time on an H100 GPU. In contrast, the end-to-end diffusion model (O(10)M parameters) takes about 80 minutes on a T4 GPU, and approximately 9 minutes on an H100 GPU. In large-scale operational settings, such as querying the system millions of time to create large extreme-event datasets, strategies for offsetting the carbon footprint should be considered. One option is to run inference on different cloud locations; for instance, 100 hours on an A100 GPU based on an Amazon AWS EC2 instance located in Canada (Central) can produce 0.5 kg CO2Eq., fully offset by renewable energy. By contrast, the same located in the US (North Virginia) can produce 9.25 kg CO2Eq. with no offset at all (these estimations were made using the Machine Learning Impact calculator).

Advantageously, the mean field model of the systems and methods disclosed herein captures deterministic large-scale features, while the diffusion model captures stochastic, fine-scale features, in a computationally-efficient manner. This further allows for dynamically-consistent downscale of climate variables, excellent performance when modeling extreme events with full spectral recovery and pointwise statistics, the user of much smaller and computationally-efficient correction-diffusion models, and faster modeling inference times as well as lower memory and carbon footprint when compared to existing end-to-end-diffusion models.

Having thus described the systems and methods in detail, it is to be understood that the foregoing description is not intended to limit the spirit or scope thereof. It will be understood that the embodiments of the present disclosure described herein are merely exemplary and that a person skilled in the art can make any variations and modification without departing from the spirit and scope of the disclosure. All such variations and modifications, including those discussed above, are intended to be included within the scope of the disclosure. What is desired to be protected by Letters Patent is set forth in the following claims.

What is claimed is:

1. A machine learning system for weather modeling, comprising:
a weather modeling processor; and
a weather modeling engine executed by the processor, the weather modeling engine causing the processor to:
receive a dataset including a plurality of vorticity samples;
process the dataset using a deterministic mean model having a temporal attention unit to model spatial, cross-channel, and temporal dependencies using dynamical attention units; and
process output of the deterministic mean model using a reverse diffusion model to capture stochastic fine scale features and to generate a denoised output.

2. The system of claim 1, wherein the deterministic mean model comprises a spatial encoder, the temporal attention unit, and a spatial decoder.

3. The system of claim 1, wherein the reverse diffusion model comprises a spatial encoder, a channel attention unit, and a spatial decoder.

4. The system of claim 3, wherein the reverse diffusion model executes a denoising score function model.

5. The system of claim 1, wherein the deterministic mean model is trained using a weighted combination of mean absolute error (MAE), mean squared error (MSE), and physics-based losses on advection, vorticity, and divergence of wind fields.

6. The system of claim 5, wherein the diffusion model is trained using a score-matching loss.

7. The system of claim 1, wherein the weather modeling engine further causes the weather modeling processor to execute a downscaling pipeline.

8. The system of claim 7, wherein the downscaling pipeline comprises a bilinear interpolation module and a deterministic UNet-based regression model.

9. A machine learning method for weather modeling, comprising:
receiving by a weather modeling processor a dataset including a plurality of vorticity samples;
processing the dataset using a deterministic mean model having a temporal attention unit to model spatial, cross-channel, and temporal dependencies using dynamical attention units; and
processing output of the deterministic mean model using a reverse diffusion model to capture stochastic fine scale features and to generate a denoised output.

10. The method of claim 9, wherein the deterministic mean model comprises a spatial encoder, the temporal attention unit, and a spatial decoder.

11. The method of claim 9, wherein the reverse diffusion model comprises a spatial encoder, a channel attention unit, and a spatial decoder.

12. The method of claim 11, wherein the reverse diffusion model executes a denoising score function model.

13. The method of claim 9, further comprising training the deterministic mean model using a weighted combination of mean absolute error (MAE), mean squared error (MSE), and physics-based losses on advection, vorticity, and divergence of wind fields.

14. The method of claim 13, further comprising training the diffusion model using a score-matching loss.

15. The method of claim 9, further comprising executing a downscaling pipeline.

16. The method of claim 15, wherein the downscaling pipeline comprises a bilinear interpolation module and a deterministic UNet-based regression model.
